(19) United States
(12) Patent Application Publication
(10) Pub. No.: US 2018/0146807 A1
(43) Pub. Date: May 31, 2018

(54) POSITIONALLY STABLE TRAVEL PILLOW

(71) Applicants: Abbye Silver, Waco, TX (US); Roy Whitehead, Waco, TX (US)

(72) Inventors: Abbye Silver, Waco, TX (US); Roy Whitehead, Waco, TX (US)

(21) Appl. No.: 15/362,449

(22) Filed: Nov. 28, 2016

(51) Int. Cl. A47G 9/10; A47G 9/02; H01L 31/046; H02S 40/38

(52) U.S. Cl. CPC A47G 9/1045; A47G 9/1009; A47G 9/1036; A47G 9/1081; A47G 2009/001; H01L 31/046; H02S 40/38; A47G 2009/1018; A47G 9/0253

(57) ABSTRACT

A form fitting travel pillow having a unique shape that provides positional stability in relation to the wearer's shoulders, and further allows for comfortable use of headphones, is disclosed. The travel pillow is formed with upper and lower concave sections such that the lower concave section fits over and conforms to the wearer's shoulders, while the upper concave section is formed such that the wearer can comfortably wear headphones. In one preferred embodiment, the travel pillow may also include a front snap or latching element to assist in maintaining a proper position of the pillow. The travel pillow may be manufactured from memory foam, and may also include a removable cover that can be readily washed or cleaned. In one embodiment, the travel pillow may also include an attached pocket or bag into which the travel pillow may be easily stowed.

### FIELD OF THE INVENTION

The present invention generally relates to the field of pillows, and more particularly relates to pillows used by travelers on airplanes and trains to assist in providing support to the traveler's head while resting and traveling. In further embodiments, the present invention is a travel pillow with one or more additional convenience features and components including a built-in cooling fan, neck and massage vibration elements, built-in speakers, exterior cover photovoltaic solar cells, and other components as described and disclosed herein.

### BACKGROUND DESCRIPTION AND REVIEW OF CERTAIN PRIOR ART

People who travel frequently on airplanes, trains, and motor vehicles (as passengers), often use some of the “downtime” by sleeping during the travel period. As most people know, trying to sleep while sitting in an upright position is difficult. To address this issue, various travel pillows, including those by the applicant, have been designed and commercialized. There is today a fairly broad and robust market for various types of travel pillows.

While there are many different styles and types of travel pillows, there are still issues with and improvements that can be made to such products to address the various needs of travelers. One such recurring issue of travelers is that many pillows are simply not comfortable to use. The pillows are bulky, and tend to shift or move about. Moreover, because many travelers use headphones when they travel to listen to music, other content, or simply for sound suppression, such travelers have found that current pillow designs are not designed with headphone usage in mind, and in particular are not designed to allow a user's headphones to comfortably stay in place. Indeed, current pillow designs tend to push the headphones out of position from the user's ear thereby preventing clear listening to the content being played, and also causing the user discomfort with the out of place headphones.

A travel pillow that is positionally stable, form fitting to both the user's shoulders and ears, is comfortable, and is readily storable, has not been created, disclosed, or used in the prior art.

Similarly, when travelling in trains or airplanes, cooling ventilation may be lacking. It would be beneficial for a travel pillow to further include a cooling fan for use when wearing a travel pillow.

While others have designed variations of travel pillows, some of which may appear to address some of the issues and problems identified above, none of these designs fully address or resolve the noted problems.

More particularly, U.S. patent application Ser. No. 12/171,014 for a Pillow To Provide Direct Head, Neck, Jaw and Chin Support, and To Relax Cervical and Shoulder Muscles, filed by Yang, teaches a neck-support pillow comprising a resilient pillow body having a column-shaped medial portion and two cantilever arms. The Yang Application does not disclosure or teach a design for a travel pillow that has concave sections in the upper and lower arm elements to provide for positional stability of the travel pillow while also allowing the user to comfortably wear headphones.

Further, U.S. patent application Ser. No. 13/488,443 for a Travel Pillow with Lateral and Rear Support Bar and a Flat and Thin Back, filed by Sternlight et al., teaches a U-shaped travel pillow having a base cushion and raised cushion fixed to the top side of the base cushion. The Sternlight et al. application similarly does not disclose or teach a pillow design that incorporates any concave sections to provide for positional stability while being used. Instead, Sternlight et al. teaches an ergonomic raised design to provide lateral support for the user's head and neck.

An original design, previously conceived by one of the applicants herein, U.S. Pat. No. 6,230,349, for a Travel Pillow, issued to Silver et al., discloses a travel pillow having a compact size and a U-shape for cradling the head and neck of a user while sitting in repose in a high-backed chair or seat. While a very effective and useful design, the Silver et al. patent design, similar to the other noted prior products and designs, does not include any concave sections or positional stability indentations.

The use of air filters in a travel pillow is shown in U.S. Pat. No. 7,195,660 for a Pillow with Air Filter, invented by Little et al., and owned by Brookstone Purchasing, Inc. The '660 patent teaches a travel pillow with one or more air filters incorporated into the body of the pillow and powered by a power source located within the pillow. The '660 patent does not disclose or teach any element of a pillow design that includes or uses any concave sections to provide augmented positional stability.

Additional features and components of a travel pillow that would be useful for many users include built-in speakers, a built-in fan for cooling and air circulation, a neck massage vibration element, rechargeable batteries to power the speakers, fan or neck massage element, flexible solar panels for power collection, and a USB port to charge certain electronic devices, such as a smartphone from the rechargeable batteries.

### SUMMARY OF THE INVENTION

The present invention overcomes the disadvantages of the prior art and fulfills the needs of users as described above by providing a positionally stable travel pillow that is designed and shaped to be worn with headphones, and may include additional convenience components.

One preferred embodiment of the invention is a travel pillow, comprising a substantially U-shaped pillow having two approximately equal length arms forming the sides of the U-shape, and a back section integrally connecting said two arms; wherein each of said arms is formed with an upper and lower concave section located approximately between a middle section of each of said two arms and said back section to provide positional stability against a user's shoulders.

A second embodiment of the invention is a travel pillow, comprising a substantially U-shaped pillow having two approximately equal length arms forming the sides of the U-shape, and a back section integrally connecting said two arms; wherein each of said arms is formed with an upper and lower concave section located approximately between a middle section of each of said two arms and said back section to provide positional stability against a user's shoulders, and wherein the upper concave sections have an indentation of approximately 10% to 25% of a thickest section of said U-shaped pillow, and the lower concave sections have an indentation of approximately 0% to 5% of a thickest section of said U-shape pillow.

A third embodiment of the invention is a travel pillow, comprising a substantially U-shaped pillow having two approximately equal length arms forming the sides of the U-shape, and a back section integrally connecting said two arms; wherein each of said arms is formed with an upper and lower concave section located approximately between a middle section of each of said two arms and said back section to provide positional stability against a user's shoulders, and further including an attached bag into which said travel pillow arms and back section may be folded and stowed.

A fourth embodiment of the invention is a travel pillow, comprising a substantially U-shaped pillow having two approximately equal length arms forming the sides of the U-shape, and a back section integrally connecting said two arms; wherein each of said arms is formed with an upper and lower concave section located approximately between a middle section of each of said two arms and said back section to provide positional stability against a user's shoulders, and further comprising an integral electric fan for cooling and air circulation.

A fifth embodiment of the invention is a travel pillow, comprising a substantially U-shaped pillow having two approximately equal length arms forming the sides of the U-shape, and a back section integrally connecting said two arms; wherein each of said arms is formed with an upper and lower concave section located approximately between a middle section of each of said two arms and said back section to provide positional stability against a user's shoulders, and further comprising rechargeable batteries used to power at least one of an electric fan, audio speakers, neck and shoulder massage vibration elements.

A sixth embodiment of the invention is a travel pillow, comprising a substantially U-shaped pillow having two approximately equal length arms forming the sides of the U-shape, and a back section integrally connecting said two arms; wherein each of said arms is formed with an upper and lower concave section located approximately between a middle section of each of said two arms and said back section to provide positional stability against a user's shoulders, and further comprising exterior surface flexible photovoltaic solar cells to collect electrical power that is stored in said rechargeable batteries.

### BRIEF DESCRIPTION OF THE DRAWINGS OF CERTAIN EMBODIMENTS

To easily identify the discussion of any particular element or act, the most significant digit or digits in a reference number refer to the figure number in which that element is first introduced.

FIG. 1 is a perspective view of an embodiment of the form fitting travel pillow showing the concave shape along the top and bottom of the two arm sections;

FIG. 2A is a top view of an embodiment of the form fitting travel pillow showing a rear storage pocket;

FIG. 2B is a top view of an embodiment of the form fitting travel pillow showing an embodiment with an air circulation fan;

FIG. 2C is a top view of an embodiment of the form fitting travel pillow showing inclusion of airflow conduits in each side arm;

FIG. 2D is a top view of an embodiment of the form fitting travel pillow showing battery storage components;

FIG. 3A is a side view of an embodiment of the form fitting travel pillow showing the concave shape that provides position support for the pillow in relation to the user's shoulders, and showing the concave shape that permits use of audio headphones;

FIG. 3B is a perspective side view of an embodiment of the form fitting travel pillow showing the concave shape that allows users to comfortably use of audio headphones;

FIG. 4 is back view of an embodiment of the form fitting travel pillow;

FIG. 5 is another back view of an embodiment of the form fitting travel pillow showing the concave shape in the back section of the pillow that provides lateral support for the user's head;

FIG. 6 is a perspective view of an embodiment of the form fitting travel pillow showing the concave shape along the top and bottom of the two arm sections and further incorporating a latch or clasp element;

FIG. 7A is a perspective view of an embodiment of the form fitting travel pillow incorporating audio speakers within each arm section;

FIG. 7B is a perspective view of an embodiment of the form fitting travel pillow incorporating audio speakers and sound directing ear cuffs within each arm section;

FIG. 8 is a perspective view of an embodiment of the form fitting travel pillow showing inclusion of vibration massage elements within the back and arm sections; and

FIG. 9A is a back view of an embodiment of the form fitting travel pillow incorporating flexible photovoltaic solar cells for power collection.

FIG. 9B is a front perspective view of an embodiment of the form fitting travel pillow incorporating flexible photovoltaic solar cells for power collection.

### DETAILED DESCRIPTION OF CERTAIN EMBODIMENTS

An innovative travel pillow designed for comfort, for positional stability in relation to the user's head and shoulders, and for use while the user wears headphones is disclosed. Further embodiments disclosed include additional features to increase the comfort of the use or utility for the user, such as built-in speakers, a built-in air circulation fan, battery storage units, and/or exterior solar cells to collect electrical power for use by a fan, or to charge a smartphone or other similar device.

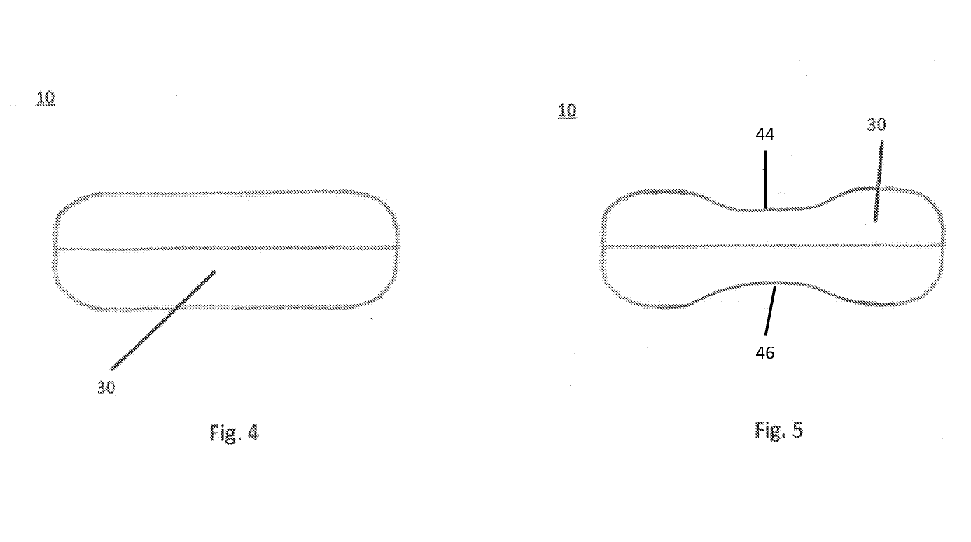

In a core embodiment, as illustrated in FIGS. 1, 2A, 3A, and 4, the travel pillow 10 has three integrally formed sections: two arms 20a, 20b and a back section 30 formed into a unitary generally “U-shaped” pillow. The arms 20a, 20b and back section 30 forming the “U-shaped” pillow create an interior opening 33 such that the pillow 10 may easily and comfortably encircle the user's neck area and support the user's head in an approximate upright position. The pillow 10 should be manufactured from a pliable, soft material that is comfortable when a user wears the travel pillow around his or her neck, and yet is firm enough to provide support to the user's head and neck.

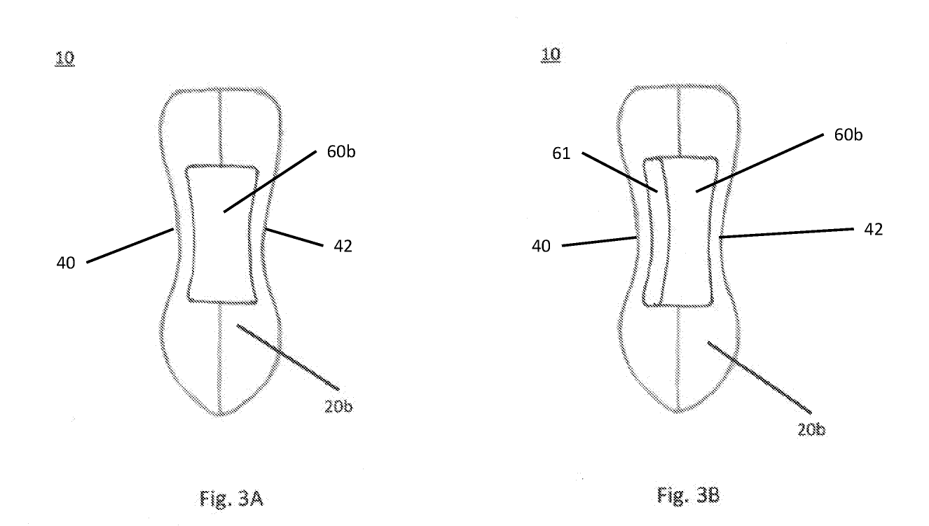

In a key element of the disclosed innovation, each of the pillow arms is molded and manufactured to have a concave shape, as shown in FIGS. 1 and 3A, on both the top 40 and bottom 42 of each arm 20a, 20b. The concave shape 42 at the bottom of each pillow arm allows the pillow to fit over the shoulder area of the user, and to provide positional stability for the pillow in relation to the user's shoulders and head. In other words, with the concave shape 42 on the bottom on each pillow arm 20a, 20b, the pillow will not rotate, twist, or in advertently move out of position. Similarly, each pillow arm 20a, 20b has a concave shape 40 on the top of each arm. The concave shape 40 on the pillow arm top allows the user to wear headphones, such as Beats® headphones or other larger fully enclosed ear covers, as shown in FIG. 3B, without the pillow pushing the headphones out of position on the user's ears.

While the concave shapes on the top 40 and bottom 42 of the pillow arms 20a, 20b are shown in FIGS. 1A and 3A, having approximately the same amount of indentation or cutout, the travel pillow 10 may, with equal utility, have different amounts of indentation. Accordingly, the concave shape 40 on the top of each pillow arms 20a, 20b, may have a different concave shape 42 provided on the bottom of the pillow arms. While different amounts of curvature may be used for the concave shapes 40, 42, with more curvature, or depth, providing additional positional stability about a user's shoulders, curvatures in the range of 10% to 25% of the thickest section of the pillow 10 appear to provide good positional stability along with high levels of user comfort. In one particular embodiment, the curvature or indentation on the top of the pillow arms may be in the range of 10% to 25%, while the curvature or indentation on the bottom of the pillow arms may be in the range of 0% to 5%.

As shown in FIG. 5, the pillow 10 may also include a concave shape along the top 44 or bottom 46 of the end section 30. By having a concave shape 44 along the top of the end section 30, positional lateral support is further provided to the user's head, especially where the user's head is more upright or tilted slightly aft. Indentation range of the top 44 or bottom 46 concave shape may be in the range of approximately 0% to 25% of the thickest section of the end section 30 of the travel pillow 10.

The travel pillow 10 may be manufactured from different types of compressible foam, such as memory foam, low-resilience or viscoelastic polyurethane foam, or polyethylene foam, or other cushionable materials. Memory foams provide excellent cushioning and support for the user and are designed to return to the original shape and curvature when not in use or under external pressure.

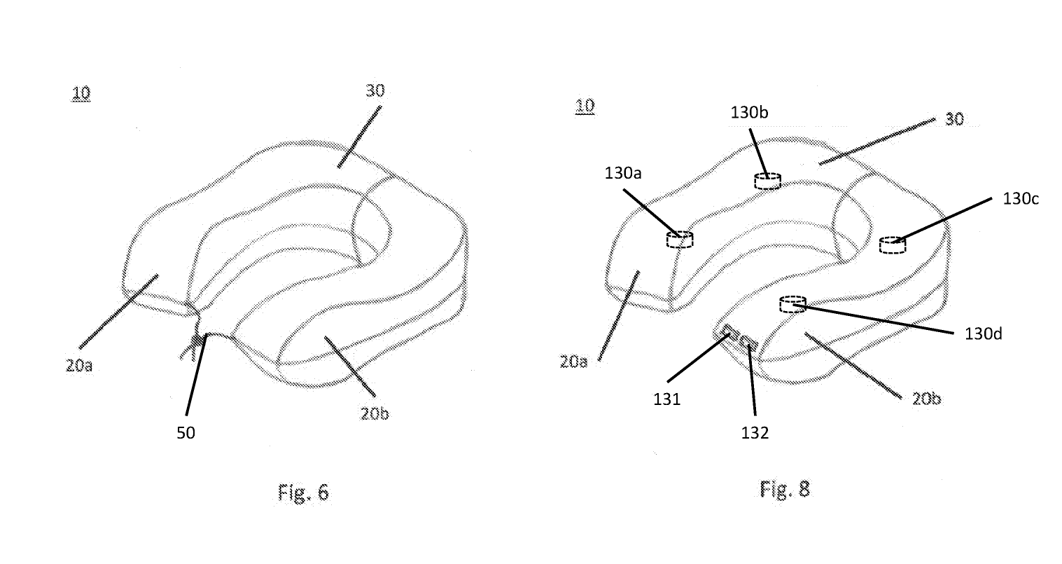

In a further embodiment, a connecting element 50 may be incorporated to the front of arms 20a and 20b, as shown in FIG. 6. The connecting element 50 can loosely hold the two arms in close proximity to each other and thereby allow the pillow 10 to retain its general circular shape and provide the desired support to the user's head and neck. Without a connecting element 50, the arms 20a and 20b may have a tendency to simply move to the side, essentially flattening out the U-shape of the pillow 10. The connecting element 50 may be manufactured as a hook and loop textile element, a snap device, a button and button hole, a button and loop, or magnets embedded within the ends of the arms 20a, 20b, or embedded within small sleeve sections incorporated into the ends of the arms 20a and 20b.

A further embodiment of the pillow may include a removable cover 100 that fully encapsulates the pillow material. The removable cover 100 may be washable, to ensure a clean surface at all times, and may also be hypoallergenic to ensure that users who may have certain allergies or allergic reactions are fully comfortable using the pillow.

For additional convenience for users, the pillow 10 may further include a pocket 60a, 60b on one or both sides of the arms 20a, 20b as illustrated in FIGS. 1 and 3A. The pockets 60a, 60b may be made from a solid material, similar to the removable cover 100 material, or may be an elastic mesh to allow the user to see what is stowed in the pockets 60a, 60b. The size of the pockets 60a, 60b should be large enough to hold a smart phone, earbuds, cards, or tickets, such as a train ticket or airline boarding pass. The pockets 60a, 60b could further be manufactured with a closing flap 61 or top cover to ensure the contents of the pocket are retained within the pockets 60a, 60b. The pockets 60a, 60b could alternatively be manufactured with a zipper closing element along the opening of the pocket 60a, 60b to retain anything that may be stored within the pocket.

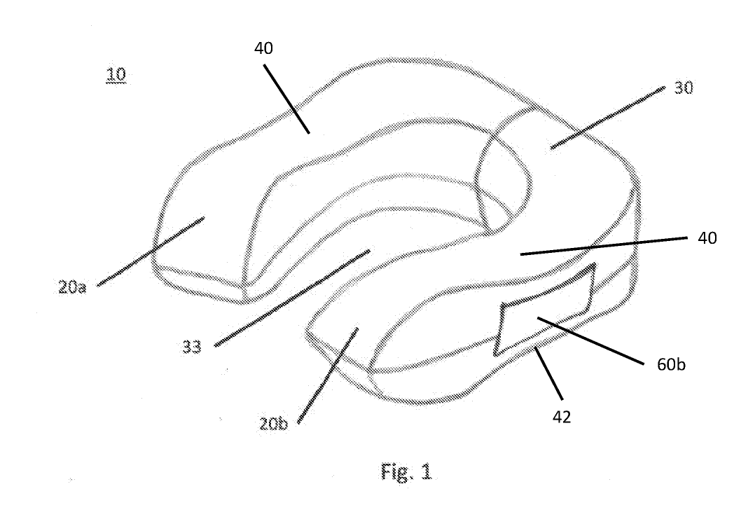

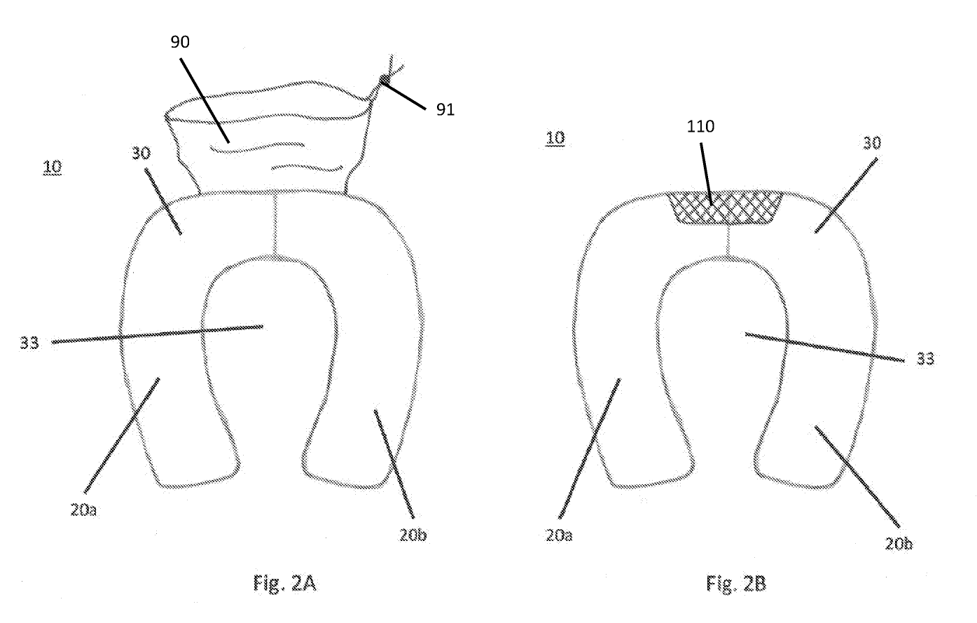

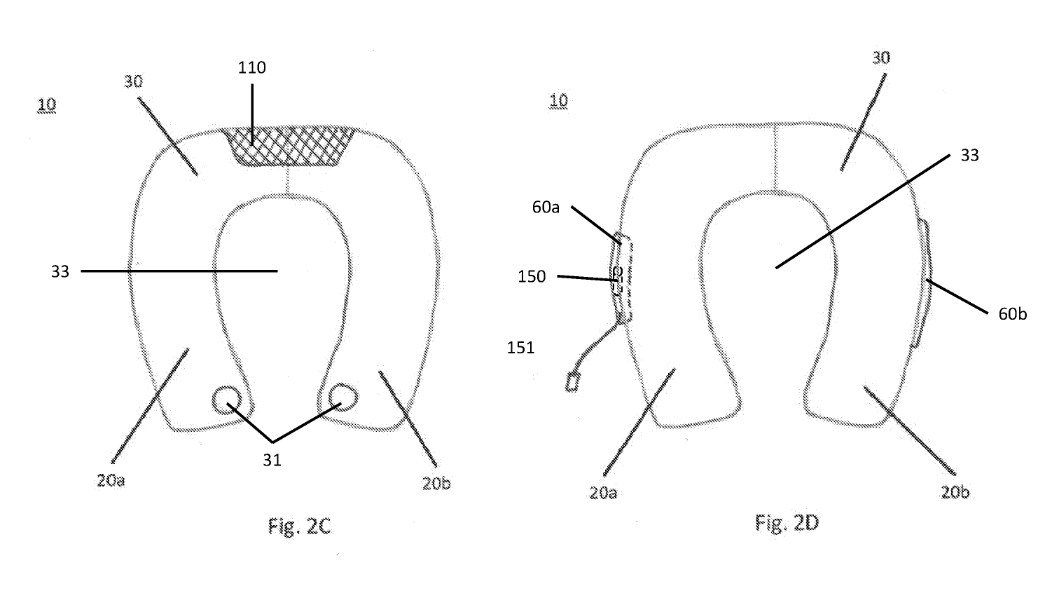

As illustrated in FIG. 2A, the pillow 10 could further include a storage pocket or storage bag 90 into which the pillow 10 may be folded to provide a compact, easily storable or packable pillow 10. The storage pocket 90 although shown incorporated into the back section 30, may also be incorporated into either of the arms 20a or 20b. Further, the storage pocket or bag 90 may include a drawstring 91 element to retain the folded pillow 10 within the storage pocket or bag 90.

In further embodiments, the pillow may comprise one or more of several different convenience components to increase the utility and desirability of using the travel pillow. One of those components, as shown in FIG. 2B is a built-in electric fan 110. Such a fan could provide cooling comfort to the wearer as well as to ensure continuing air circulation. While the electric fan 110 is shown incorporated into the top back section 30 of the travel pillow, the pillow may also be designed to include sections or conduits 31 to direct some or all of the fan 110 air flow through and out of both arms 20a, 20b, as shown in FIG. 2C, and thereby provide circulating air to the front of the pillow and proximate to the user's face.

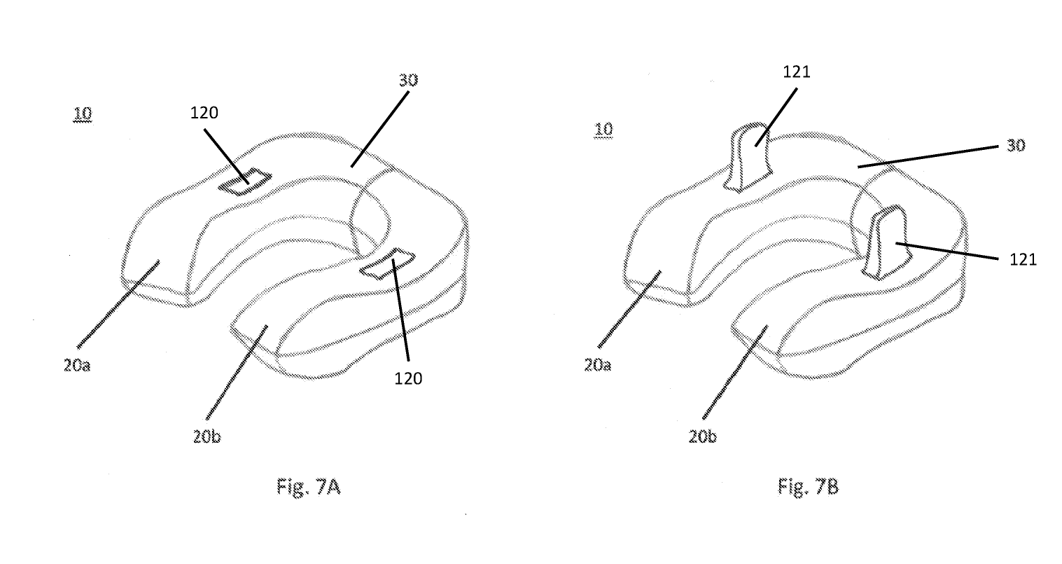

Another component to include in the travel pillow 10 are single or dual speakers 120 that provide audio output in close proximity to the user's ears, as illustrated in FIG. 7A. The speakers may receive audio content to be played through the speakers 120 through a wireless connection, such a Bluetooth®, or may alternatively receive audio content by a wired audio connector, such as from an iPod® or smartphone. A volume control for the audio output may further be incorporated into the travel pillow 10, such as shown in FIG. 7A.

Because use of a travel pillow is often times in close proximity to other travelers, such as on a commercial airliner, or on a train, and a user may wish to control or limit the wide area broadcasting of the audio stream. As such, another embodiment of the travel pillow 10 that incorporates dual speakers 120, may further include ear-speaker cuffs 121 that flexibly extend from the speaker face or source to the user's ears as shown in FIG. 7B. Such ear-speaker cuffs 121 may be made of the same material as the removable cover 100, or alternatively may be manufactured from a different type of material that is comfortable to wear over one's ears.

A further embodiment of the travel pillow 10 for use to provide users with a direct neck and/or shoulder massage includes one or more vibration elements 130 incorporated into the pillow arm sections 20a, 20b, and back section 30, as shown in FIG. 8. This embodiment may have one vibration element 130a incorporated into the back section 30, or may have a plurality of vibration elements 130a, 130b, 130c that are spaced within the back section 30 and arm sections 20a and 20b to provide localized massage vibrations to the user's neck and shoulders. For the user's control, an on-off switch 131, and an intensity control 132 may also be incorporated into the pillow 10, as illustrated in FIG. 8.

For each of the above convenience elements, including the fan 110, speakers 120, and vibration elements 130, electrical power is likely required. Accordingly, an embodiment of the travel pillow 10, as shown in FIG. 2D, may also include a pocket 60a, compartment or section, within the pillow 10, to hold batteries 150. The batteries 150 may power one or more of the fan 110, speakers 120, and/or vibration elements 130. The batteries 150 may be non-rechargeable and disposable, or rechargeable. The travel pillow 10 may also simply have a USB connector 151, as illustrated in FIG. 2D, to allow the user's laptop or other electronic device to power the fan 110, speakers 120, and/or vibration elements 130. The battery pack may also be used to recharge a separate device such as a smartphone. For such capability, the travel pillow 10 could have a USB connector or outlet to allow charging of a smartphone or other electronic device.

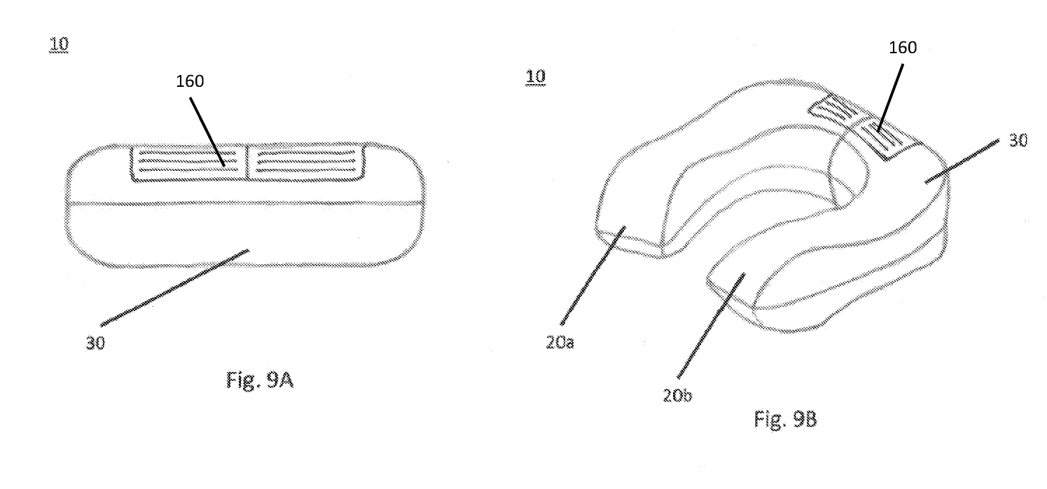

As an alternative to removable rechargeable batteries 150, in a further embodiment, the travel pillow may further incorporate on an exterior surface, flexible photovoltaic solar cells 160 as illustrated in FIGS. 9A and 9B. In such a configuration, a plurality of the solar cells 160 would cover a limited exterior section of the travel pillow 10, preferable along a side section or the back section, as shown in FIG. 9B, to not be uncomfortable to the user when the travel pillow 10 is in use. The solar cells 160 would collect electrical power when the pillow exterior is facing sunlight or other bright light sources, and then store such collected power in the rechargeable batteries 150 for later use.

While preferred embodiments of the inventive travel pillow have been described and disclosed, in particular with reference to certain figures and exemplary embodiments of the travel pillow, such exemplary representations are not to be construed as limiting the scope of application of the inventive product and device. By way of example, other cushioning materials, other than polyethylene or polyurethane (memory foam), may be used to provide the cushioning of the pillow, and similarly, alternative power or electrical connections, other than the disclosed batteries or USB connector, may be incorporated into an embodiment of the travel pillow with equal utility.

It will be recognized by those skilled in the art that other modifications, substitutions, and/or other applications are possible and all such modifications, substitutions and applications are within the true scope and spirit of the present invention. It is likewise understood that the above disclosure and attached claims are intended to cover all such modifications, substitutions, and/or applications.

What is claimed is:

1. A travel pillow, comprising:
a substantially U-shaped pillow having two approximately equal length arms forming the sides of the U-shape, and a back section integrally connecting said two arms;
wherein each of said arms is formed with an upper and lower concave section located approximately along a middle section of said length of each of said two arms to provide positional stability against a user's shoulders.

2. The travel pillow of claim 1, wherein said upper and lower concave sections have an indentation of approximately 10% to 25% of a thickest section of said U-shaped pillow.

3. The travel pillow of claim 1, wherein said upper concave sections have an indentation of approximately 10% to 25% of a thickest section of said U-shaped pillow, and said lower concave sections have an indentation of approximately 0% to 5% of a thickest section of said U-shape pillow.

4. The travel pillow of claim 1, wherein said upper and lower concave sections have an indentation of approximately 0% to 5% of a thickest section of said U-shaped pillow.

5. The travel pillow of claim 1, wherein said two arms and said back section are manufactured from memory foam.

6. The travel pillow of claim 1, wherein said two arms and said back section are manufactured from low-resilience polyurethane.

7. The travel pillow of claim 1, further comprising a removable form fitting cover that fully encapsulates said U-shaped pillow two arms and back section.

8. The travel pillow of claim 7, wherein said removable form fitting cover is manufactured from a hypoallergenic material.

9. The travel pillow of claim 7, wherein said removable cover is washable.

10. The travel pillow of claim 1, further comprising front latch element to hold the open end of said U-shaped pillow together.

11. The travel pillow of claim 10, wherein said latch element is at least one of a snap device, a pair of magnets, a button and hole, a hook and loop textile materials, and a button and loop.

12. The travel pillow of claim 1, wherein said back section further comprises an upper concave section located approximately in a middle section of said back section.

13. The travel pillow of claim 1, wherein said back section further comprises an upper and lower concave section located approximately in a middle section of said back section.

14. The travel pillow of claim 1, further comprising at least one side pocket formed into at least one of said arms.

15. The travel pillow of claim 14, wherein at least one of said at least one side pockets has a zipper closing element.

16. The travel pillow of claim 14, wherein at least one of said at least one pockets has a flap cover over said pocket opening.

17. The travel pillow of claim 1, further comprising an attached bag into which said travel pillow arms and back section may be folded and stowed.

18. The travel pillow of claim 1, further comprising an integral electric fan for cooling and air circulation.

19. The travel pillow of claim 4, further comprising an integral electric fan for cooling and air circulation.

20. The travel pillow of claim 1, wherein said integral electric fan is powered by one of at least removal disposable batteries, removable rechargeable batteries, or external power transmitted through a USB cable.

21. The travel pillow of claim 1, further comprising an audio speaker built into each of said arms approximately at a middle section of said upper concave section.

22. The travel pillow of claim 21, further comprising cuff elements over said audio speakers that fit over a user's ears.

23. The travel pillow of claim 1, further comprising neck and shoulder massage vibration elements.

24. The travel pillow of claim 1, further comprising rechargeable batteries used to power at least one of an electric fan, audio speakers, neck and shoulder massage vibration elements.

25. The travel pillow of claim 24, further comprising exterior surface flexible photovoltaic solar cells to collect electrical power that is stored in said rechargeable batteries.
